(19) United States
(12) Patent Application Publication
(10) Pub. No.: US 2025/0034746 A1
(43) Pub. Date: Jan. 30, 2025

(54) METHOD FOR MANUFACTURING A BIPOLAR PLATE FOR POLYMER ELECTROLYTE MEMBRANE WATER ELECTROLYSIS

(71) Applicant: SEOUL NATIONAL UNIVERSITY R&DB FOUNDATION, Seoul (KR)

(72) Inventors: Suk Won CHA, Seoul (KR); In Won CHOI, Seoul (KR); Sangbong YU, Seoul (KR); Wonyeop JEONG, Seoul (KR); Yangjae KIM, Seoul (KR)

(21) Appl. No.: 18/709,385

(22) PCT Filed: Mar. 31, 2022
(86) PCT No.: PCT/KR2022/004613

§ 371 Date: May 10, 2024

(30) Foreign Application Priority Data
Nov. 10, 2021 (KR) 10-2021-0153723

(51) Int. Cl. C25F 3/24; C25B 13/05

(52) U.S. Cl. CPC C25F 3/24; C25B 13/05

(57) ABSTRACT

The present disclosure relates to a method for manufacturing a bipolar plate, and the method for manufacturing a bipolar plate according to the present disclosure is for use in a polymer electrolyte water electrolysis device, the method characterized to include a shape-processing step of processing a shape using stainless steel; a polishing step of polishing the processed shape surface; and a coating step of coating the polished surface with a highly corrosion-resistant material.

### FIELD

The present disclosure relates to manufacturing a bipolar plate, and more particularly, to a method for manufacturing a bipolar plate for use in a polymer electrolyte membrane water electrolysis device, wherein the bipolar plate has a channel formed to supply water and separate gas generated through splitting of the water, and that supports a Membrane and Electrode Assembly (MEA) to form a stack.

### BACKGROUND

A fuel cell is a device that generates electricity using fuel. Unlike ‘primary batteries’, which are used once and discarded like batteries, and ‘secondary batteries’, which are used repeatedly to charge and discharge, like lithium-ion batteries, fuel cells can be used continuously by injecting fuel, and so they are classified as ‘tertiary batteries’. At an anode, oxidation of fuel occurs, and at a cathode, reduction of oxygen occurs, and the energy released through an entire reaction is utilized externally in the form of electricity. Since fuel cells have high power generation efficiency and are environmentally friendly, they are attracting attention as a future energy source.

The entire system can be comprised of a water electrolysis device for producing hydrogen to be used as a fuel for fuel cells, and a fuel cell for generating electricity using the generated hydrogen, and the water electrolysis device and the fuel cell are known to have similar configurations.

Recently, a highly efficient water electrolysis device using a solid polymer electrolyte membrane as a water electrolysis device has been attracting attention. Polymer electrolyte water electrolysis devices do not require electrolyte management because the electrolyte is a solid polymer, and because only pure water is used, there are no problems of corrosion or contamination. In addition, an anode electrode and a cathode electrode are separated with a solid polymer electrolyte membrane in between, and so the mixing of hydrogen and oxygen is fundamentally blocked, which has the advantage of being able to obtain high purity hydrogen and oxygen without a separate purification process. Further, because the current density can be used at a significantly higher level, a large amount of hydrogen and oxygen can be obtained compared to the size of the device.

FIG. 1 illustrates a schematic configuration of a polymer electrolyte water electrolysis device, which is formed in a stacked structure of a membrane and electrode assembly (MEA) 110, a bipolar plate 120, and a gasket 130, and on both sides, an end plate 140 may be coupled.

The membrane and electrode assembly 110 is composed of a polymer electrolyte membrane, hydrogen and oxygen electrode catalyst layers formed on both sides of the polymer electrolyte membrane, respectively, and an electrode layer formed on the catalyst layer. At both sides of the membrane and electrode assembly 110, the bipolar plate 120 is formed to support the membrane and electrode assembly 110, wherein a channel 122 may be formed on one side surface or on both side surfaces to facilitate discharge of gas that is generated from the water supplied and split through the bipolar plate 122.

In the case of a bipolar plate 120 of a polymer electrolyte water electrolysis device, high voltage and current are applied in a high oxygen partial pressure environment (anode side), and so materials such as low-cost stainless steel (SUS) that can be used in polymer electrolyte fuel cells are prone to corrosion and therefore cannot be used due to durability issues. Accordingly, bipolar plates made of titanium (Ti), which have high corrosion resistance, have been used as bipolar plates 120 of polymer electrolyte water electrolysis devices. However, in the case of titanium, there has been a problem of high rigidity, leading to poor processability, and high unit price, which increased the price of the entire device.

### SUMMARY

Therefore, a purpose of the present disclosure is to solve the problems of prior art mentioned above, that is, to provide a method for manufacturing a bipolar plate by performing electropolishing on an inexpensive stainless steel (SUS), and then coating it with either tantalum (Ta) or niobium (Nb), which have high corrosion resistance, in an optical thin film thickness, thereby providing a bipolar plate that has high performance that can replace conventional cases manufactured from titanium materials and at the same time be used in polymer electrolyte water electrolysis devices at a low cost.

The problems that the present disclosure intends to solve are not limited to the problems mentioned above, and other problems not mentioned will be clearly understood by those skilled in the art from the description below.

The above-mentioned purpose may be achieved by a method for manufacturing a bipolar plate for use in a polymer electrolyte water electrolysis device, the method including a shape-processing step of processing a shape using stainless steel; a polishing step of polishing the processed shape surface; and a coating step of coating the polished surface with a highly corrosion-resistant material.

The highly corrosion-resistant material may be either one of tantalum (Ta) and niobium (Nb).

Here, at the polishing step, electropolishing may be performed.

Here, the method may further include a step of mechanical polishing prior to performing the electropolishing.

Here, the electropolishing may be performed using a platinum plate as a counter electrode in an electrolyte solution containing sulfuric acid, phosphoric acid, and glycerol.

Here, the coating step may coat a thin film in a sputtering method.

According to the method for manufacturing a bipolar plate for use in a polymer electrolyte water electrolysis device of the present disclosure mentioned above, there is an advantage that it is possible to manufacture a bipolar plate having the performance that can replace the case of manufacturing with conventional titanium (Ti) materials at a low cost.

Compared to processing with conventional titanium materials, it also has the advantage of reducing the processing time and thus enabling mass production.

### BRIEF DESCRIPTION OF THE DRAWINGS

FIG. 1 is an exploded perspective view of a polymer electrolyte water electrolysis device;

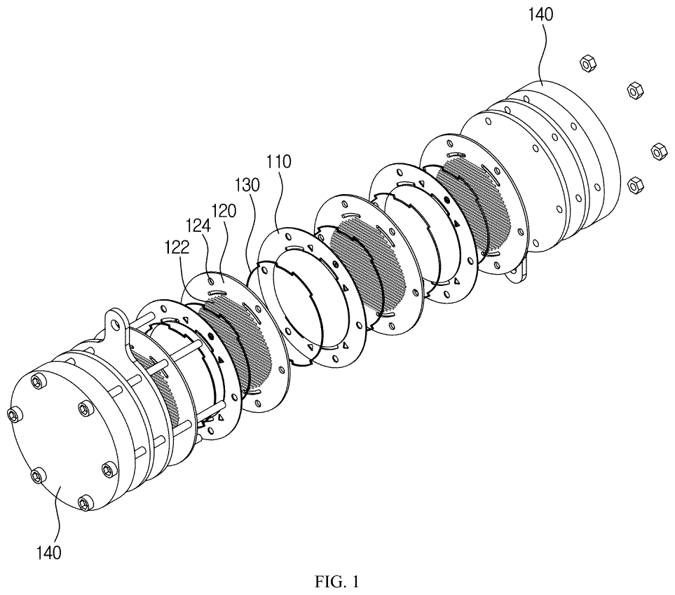

FIG. 2 is a flow chart of a method for manufacturing a bipolar plate for use in a polymer electrolyte water electrolysis device according to an embodiment of the present disclosure;

FIG. 3 shows results of analyzing the surface roughness after mechanical polishing on stainless steel;

FIG. 4 shows results of analyzing the surface roughness after electropolishing on stainless steel;

FIG. 5 shows results of corrosion tests conducted on specimens coated with tantalum (Ta) after mechanical or electropolishing on stainless steel;

FIG. 6 shows results of corrosion tests confirming the corrosion performance of a specimen coated with tantalum (Ta) on stainless steel; and

FIG. 7 shows results of testing the actual performance of a bipolar plate coated with tantalum (Ta) on stainless steel manufactured according to the present disclosure, a bipolar plate manufactured from titanium and a bipolar plate manufactured from stainless steel.

### DETAILED DESCRIPTION

Specific details of the embodiments are included in the detailed description and drawings.

The advantages and features of the present disclosure and methods for achieving them will become clear by referring to the embodiments described in detail below along with the accompanying drawings. However, the present disclosure is not limited to the embodiments disclosed below and may be implemented in various different forms, and thus the present embodiments are merely provided to ensure that the disclosure of the present disclosure is complete and to fully inform those skilled in the technical field to which the present disclosure pertains the scope of the disclosure, and the present disclosure is only defined by the scope of the claims. Like reference numerals refer to like elements throughout the specification.

Hereinbelow, the present disclosure will be described with reference to the drawings for describing a method for manufacturing a bipolar plate for use in a polymer electrolyte water electrolysis device by embodiments of the present disclosure.

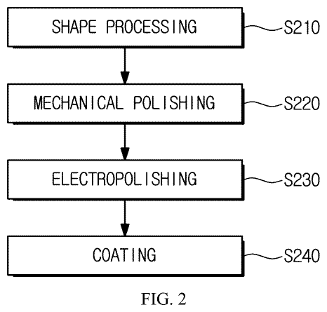

FIG. 2 is a flow chart of a method for manufacturing a bipolar plate for use in a polymer electrolyte water electrolysis device according to an embodiment of the present disclosure.

A method for manufacturing a bipolar plate 120 for use in a polymer electrolyte water electrolysis device according to an embodiment of the present disclosure can replace a bipolar plate 120 manufactured from expensive titanium, which is mainly used in the fuel electrode of the conventional polymer electrolyte water electrolysis device.

A method for manufacturing a bipolar plate 120 for use in a polymer electrolyte water electrolysis device according to an embodiment of the present disclosure may include a shape processing step of processing the shape using stainless steel (SUS) (S210), a polishing step of polishing the processed shape surface (S220, S230), and a coating step of coating the polished surface with highly corrosion resistant material (S240).

In the present disclosure, stainless steel (SUS) is used as a base material for manufacturing the bipolar plate 120. Stainless steel has advantages of being very inexpensive and highly processable compared to titanium, which has been used in manufacturing conventional bipolar plates.

First, the shape of the bipolar plate 120 is processed using stainless steel as the base material (S210). On one side surface or both side surfaces of the bipolar plate 120, multiple channels 122 through which gas separated from water can pass are formed, and a hole 124 for fixed connection may be formed. Therefore, through mechanical processing such as CNC milling and the like, the shape of the bipolar plate 120 that includes the channel 122 or hole 124 may be processed.

Next, the processed shape surface is polished. Here, in the present disclosure, it is desirable to perform electropolishing. Details on this will be explained later.

Mechanical polishing may be performed prior to electropolishing (S230) (S220). Mechanical polishing polishes the shape-processed base material in the order of 220 grit and 600grit. In this embodiment, mechanical polishing is performed using 600 grit sandpaper, followed by electropolishing. By performing mechanical polishing prior to performing electropolishing, it is possible to shorten the electropolishing time and increase the polishing uniformity of the surface.

After mechanical polishing, cleaning may be performed by sonicating for about 10 minutes in the following order: acetone, isopropyl alcohol, and deionized water.

Here, the cleaned bipolar plate 120 is immersed in an electrolyte containing sulfuric acid, phosphoric acid, and glycerol, and connected to a working electrode for electropolishing. Here, a platinum plate may be used as a counter electrode.

In order to find an appropriate voltage to perform the electropolishing, it is desirable to connect a Potentiostat to measure an IV graph, check the voltage area for electropolishing from the measured IV graph, and perform the electropolishing at that voltage or at a slightly higher voltage.

After performing the electropolishing, it is possible to perform the cleaning that was performed after the mechanical polishing, again.

After performing the electropolishing or the electropolishing after the mechanical polishing as mentioned above, the surface is dried to completely remove the moisture, and coating is performed on the polished surface (S240).

In the case of the bipolar plate 120 used in the polymer electrolyte water electrolysis device, conductivity is required and high voltage and current are applied in a high oxygen partial pressure environment (anode side), so materials such as stainless steel that can be used in conventional polymer electrolyte fuel cells cannot be used due to corrosion durability issues. Accordingly, in the present disclosure, the polished surface may be coated with a material having high corrosion resistance. For example, by coating the polished surface that is shape-processed from stainless steel, using either tantalum (Ta) or niobium (Nb), which have high corrosion resistance and are relatively inexpensive, to have a thin film of several micrometers thick, it is possible to form a dense coating film that does not corrode even in an environment of high voltage, high current, and high oxygen partial pressure at the fuel electrode of a polymer electrolyte water electrolysis device. Materials with high corrosion resistance are not limited to the above materials. The above-mentioned coating may be performed in a sputtering method.

As described above, in the present disclosure, the surface of the material is controlled (surface roughness, surface uniformity, oxide film creation) by removing surface impurities and performing electropolishing to have uniform roughness before performing the coating using the material, thereby reducing internal defects that may occur during the process of sputtering coating and also increase coating adhesion.

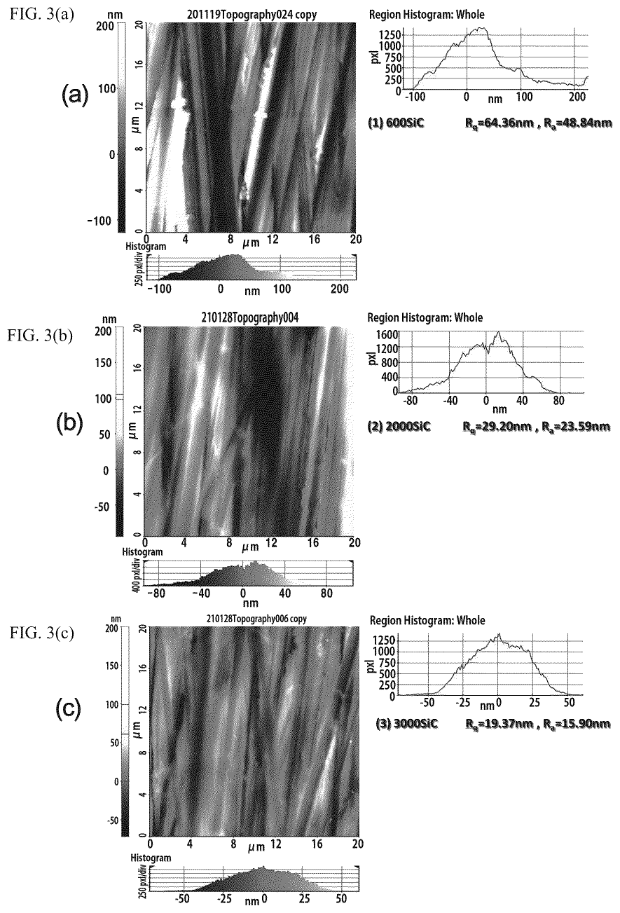

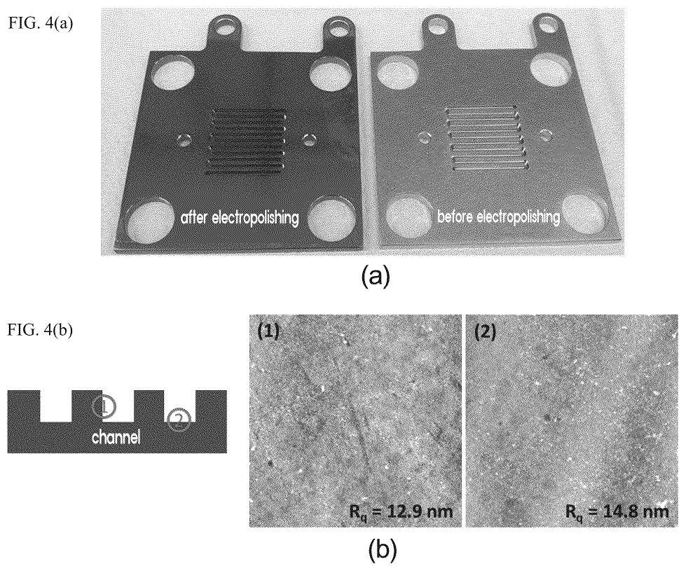

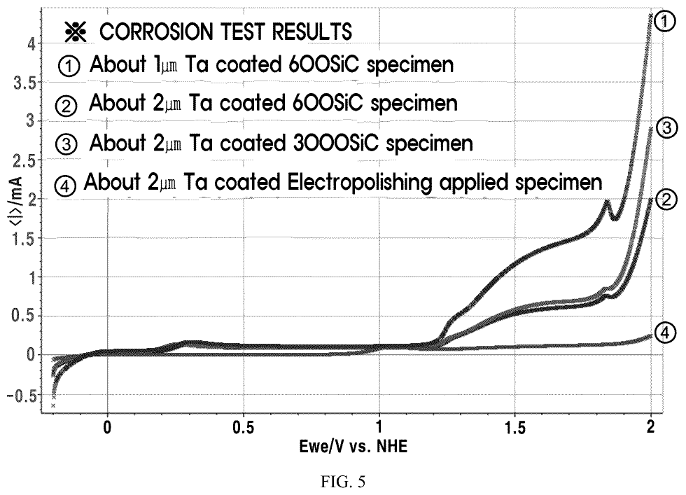

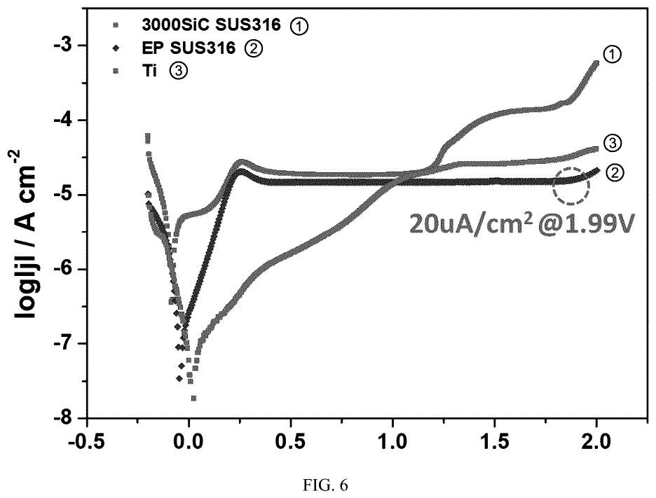

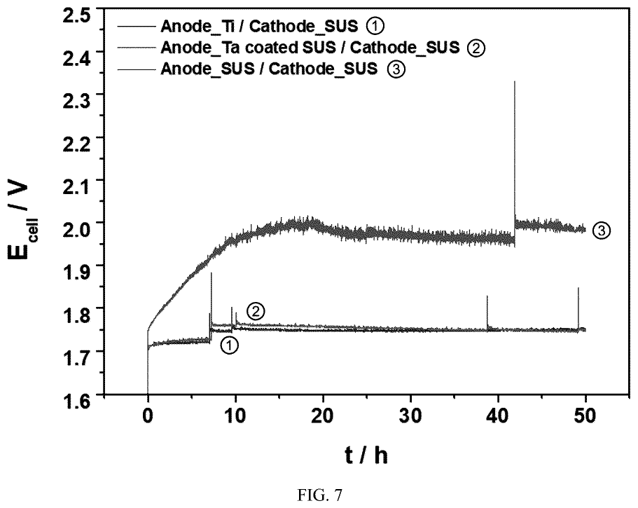

FIG. 3 shows results of analyzing the surface roughness after the mechanical polishing on stainless steel, FIG. 4 shows results of analyzing the surface roughness after the electropolishing on stainless steel, FIG. 5 shows results of corrosion tests conducted on specimens coated with tantalum (Ta) after the mechanical polishing or electropolishing on stainless steel, FIG. 6 shows results of corrosion tests confirming the corrosion performance of a specimen coated with tantalum (Ta) on stainless steel, and FIG. 7 shows results of testing the actual performance of a bipolar plate coated with tantalum (Ta) on stainless steel manufactured according to the present disclosure, a bipolar plate manufactured from titanium and a bipolar plate manufactured from stainless steel.

(a), (b), and (c) of FIG. 3 show enlarged photographs of the surface and the results of surface roughness after mechanical polishing using 600 SiC, 2000 SiC, and 3000 SiC, respectively. Analyses show that for 600 SiC, Rq=64.36 nm and Ra=48.84 nm; for 2000 SiC, Rq=29.20 nm and Ra=23.59 nm; and for 3000 SiC, Rq=19.37 nm and Ra=15.90 nm.

FIG. 4 shows (a) photographs of the bipolar plate before and after the electropolishing, and an enlarged photograph of point \textcircled{1} that is a side surface of the channel 122 after the electropolishing and point \textcircled{2} that is a bottom surface of the channel 122, and a result of surface roughness. It was confirmed that points \textcircled{1} and \textcircled{2} had relatively uniform values, with Rq=12.9 nm and Rq=14.8 nm, respectively.

It can be seen that even within the channel 122, where mechanical polishing is relatively difficult with electropolishing, polishing can be done to have a surface roughness similar to or better than mechanical polishing using 3000 SiC.

FIG. 5 illustrates results of corrosion tests confirming the corrosion performance of a specimen coated with tantalum (Ta) on stainless steel. The corrosion test simulated the environment of the anode electrode of the polymer electrolyte water electrolysis device and measured the current value according to voltage application to each specimen in an environment where 0.5M H₂SO₄ and saturated oxygen (O₂) were added at 65° C.

Considering that the voltage of the bipolar plate during water electrolysis in a high-density electrolyte water electrolysis device is 1.6 to 1.7 V, the corrosion test was conducted in the range of −0.2 to 2 V. Here, it is considered that the higher the current value in the high voltage area, the more corroded the specimen is.

As shown in FIG. 5, it can be seen that corrosion has progressed significantly in the specimen coated with Ta after the mechanical polishing as the current value rapidly increased in the high voltage area. On the other hand, it can be seen that the specimen coated with Ta after the electropolishing was not easily corroded because the current value did not increase even in the high voltage area. As explained with reference to FIGS. 4 and 5, it can be seen that the surface roughness in the case of 3000 SiC mechanical polishing and in the case of electropolishing was almost similar, whereas the resistance to corrosion was much better when Ta was coated after electropolishing. In the case where Ta is sputter-coated after the mechanical polishing, due to the characteristics of sputtering coating, there is a possibility that pinholes and defects may occur as a thin film grows, and since the surface of the specimen is uneven and rough, a 1-2 μm thick coating is not enough to sufficiently protect the specimen.

FIG. 6 shows results of performance tests conducted on a specimen electropolished from stainless steel and coated with Ta to 4 μm, a specimen mechanically polished with 3000 SiC and coated with Ta, and a specimen made of conventional titanium (Ti). As in the test of FIG. 5, the current value according to voltage application to each specimen was measured in an environment where 0.5M H₂SO₄ and saturated oxygen (O₂) were added at 65° C.

In the case of a specimen mechanically polished with 3000 SiC and coated with Ta, it can be seen that the coating film is easily peeled off and corrosion easily progresses in the high voltage area, whereas in the case of electropolishing stainless steel according to the present disclosure and coating it with Ta to 4 μm, it can be seen that the corrosion performance is almost similar to that in the case where the specimen was manufactured from conventional titanium. Good corrosion performance can be obtained by coating with a thin film of about 4 μm (coating a small amount of Ta) without thickening the coating thickness of Ta.

FIG. 7 shows results of testing the cell operation performance at a constant current 1 A/cm₂ for 50 hours using an actual electrolyte and electrode on a bipolar plate actually manufactured by electropolishing stainless steel and coating it with Ta according to the present disclosure and on a bipolar plate manufactured from stainless steel or titanium without coating.

An increase in voltage means a decrease in performance, so when a bipolar plate is manufactured only from stainless steel, the operating performance is reduced, and when a bipolar plate is manufactured according to the present disclosure, it can be seen that the performance is almost the same as when the bipolar plate was made of conventional expensive titanium.

The bipolar plate manufactured according to the present disclosure is not limited to the bipolar plate of a polymer electrolyte water electrolysis device, but can also be used as a bipolar plate of a polymer electrolyte fuel cell used in milder environmental conditions than that of a water electrolyte device.

The scope of the present disclosure is not limited to the above-described embodiments, but may be implemented in various forms of embodiments within the scope of the appended claims. It is deemed to be within the scope of the claims of the present disclosure to the extent that anyone skilled in the art can make modifications without departing from the gist of the present disclosure as claimed in the claims.

1. A method for manufacturing a bipolar plate for use in a polymer electrolyte water electrolysis device, the method comprising:
a shape-processing step of processing a shape using stainless steel;
a polishing step of polishing the processed shape surface; and
a coating step of coating the polished surface with a highly corrosion-resistant material.

2. The method for manufacturing a bipolar plate according to claim 1,
wherein the highly corrosion-resistant material is either one of tantalum Ta and niobium Nb.

3. The method for manufacturing a bipolar plate according to claim 1,
wherein the polishing step performs electropolishing.

4. The method for manufacturing a bipolar plate according to claim 3,
further comprising a step of mechanical polishing prior to performing the electropolishing.

5. The method for manufacturing a bipolar plate according to claim 3,
wherein the electropolishing is performed using a platinum plate as a counter electrode in an electrolyte solution containing sulfuric acid, phosphoric acid, and glycerol.

6. The method for manufacturing a bipolar plate according to claim 1, wherein the coating step coats a thin film in a sputtering method.
